(19) United States
(12) Patent Application Publication
(10) Pub. No.: US 2024/0302105 A1
(43) Pub. Date: Sep. 12, 2024

(54) THERMAL DIFFUSION DEVICE

(71) Applicant: Murata Manufacturing Co., Ltd., Nagaokakyo-shi (JP)

(72) Inventors: Tatsuhiro NUMOTO, Nagaokakyo-shi (JP); Tsuyoshi MUKAI, Nagaokako-shi (JP)

(21) Appl. No.: 18/663,541

(22) Filed: May 14, 2024

Related U.S. Application Data
(63) Continuation of application No. PCT/JP2022/042050, filed on Nov. 11, 2022.

(30) Foreign Application Priority Data
Nov. 16, 2021 (JP) 2021-186250

(51) Int. Cl. F28D 15/02; H05K 7/20

(52) U.S. Cl. CPC F28D 15/0266; H05K 7/20336

(57) ABSTRACT

A thermal diffusion device that includes: a housing including a first inner wall surface and a second inner wall surface facing each other in a thickness direction; a working medium sealed in an inner space of the housing; and a wick structure in the inner space of the housing, the wick structure including a supporting portion in contact with the first inner wall surface and a portion having holes composed of a same material as the supporting portion and integral with the supporting portion.

### CROSS REFERENCE TO RELATED APPLICATIONS

The present application a is continuation of International application No. PCT/JP2022/042050, filed Nov. 11, 2022, which claims priority to Japanese Patent Application No. 2021-186250, filed Nov. 16, 2021, the entire contents of each of which are incorporated herein by reference.

### TECHNICAL FIELD

The present description relates to a thermal diffusion device.

### BACKGROUND ART

In recent years, the amount of heat generation has been increasing because of high integration and high performance of elements. In addition, the size of products has been decreasing, and heat generation density has been increasing, and thus a heat dissipation countermeasure becomes important. This situation is particularly pronounced in the field of mobile terminals, such as smartphones and tablets. For example, a graphite sheet is often used as a heat countermeasure member, but the amount of heat transported by the sheet is insufficient, and the use of various heat countermeasure members has been considered. In particular, the use of a vapor chamber, which is a planar heat pipe, is under consideration as a thermal diffusion device capable of diffusing heat very effectively.

A vapor chamber has a structure in which a working medium (also referred to as a working fluid), and a wick for transporting the working medium by capillary action are sealed in a housing. The working medium absorbs heat from a heating element, such as an electronic component, in an evaporation portion that absorbs heat from the heating element, evaporates in the vapor chamber, moves in the vapor chamber, and then turns back into a liquid phase by being cooled. The working medium that has turned back into the liquid phase moves again toward the evaporation portion on the heating element side by the capillary action of the wick, and cools the heating element. By repeating this cycle, the vapor chamber, which does not have external power, is able to operate independently and diffuse heat two-dimensionally at high speed by using evaporation latent heat and condensation latent heat of the working medium.

In Patent Document 1, a thermal ground plane, which is an example of the vapor chamber, is disclosed. The thermal ground plane described in Patent Document 1 includes a first planar substrate member, a plurality of micropillars disposed on the first planar substrate member, a mesh bonded on at least a subset of the micropillars, a vapor core disposed on at least one of the first planar substrate member, the micropillars, and the mesh, and a second planar substrate member disposed on the first planar substrate member, and the mesh isolates the micropillars from the vapor core, and the first planar substrate member and the second planar substrate member enclose the micropillars, the mesh, and the vapor core.
Patent Document 1: U.S. Pat. No. 10,527,358

### SUMMARY OF THE DESCRIPTION

In the vapor chamber described in Patent Document 1, a wick includes supporting columns such as the micropillars and a body having holes such as the mesh. Among such components, the supporting columns such as the micropillars have shapes such as quadrangular prism-shapes or columnar shapes, and a liquid channel of a working medium is formed between the supporting columns. Therefore, when the width of the interval between the supporting columns is increased, the width of the liquid channel is increased, and thus the permeability is improved. On the other hand, when the liquid channel is too wide, the body having holes such as the mesh is easily depressed between the supporting columns, and thus the position of the body having holes may be displaced, and the stability of the wick may be deteriorated. For the above-reasons, it is difficult to significantly increase the width of the liquid channel, and it can be said that there is room for improvement in terms of improving the characteristics of the vapor chamber.

Note that the above-described problem is not limited to being a problem of a vapor chamber, and is a problem common to a thermal diffusion device capable of diffusing heat with a configuration similar to the vapor chamber.

The present description is made to solve the above-described problem, and an object of the present description is to provide a thermal diffusion device including a wick structure that is structurally stable even when a width of a liquid channel of a working medium is increased. In addition, an object of the present description is to provide an electronic device including the above-described thermal diffusion device.

A thermal diffusion device of the present description includes: a housing including a first inner wall surface and a second inner wall surface facing each other in a thickness direction; a working medium sealed in an inner space of the housing; and a wick structure in the inner space of the housing, the wick structure including a supporting portion in contact with the first inner wall surface and a portion having holes composed of a same material as the supporting portion and integral with the supporting portion.

An electronic device of the present description includes the thermal diffusion device of the present description.

According to the present description, a thermal diffusion device including a wick structure that is structurally stable even when a width of a liquid channel of a working medium is increased can be provided. In addition, according to the present description, an electronic device including the above-described thermal diffusion device can be provided.

### BRIEF DESCRIPTION OF THE DRAWINGS

FIG. 1 is a perspective view schematically illustrating an example of a thermal diffusion device of the present description.

FIG. 2 is an example of a sectional view taken along line II-II of the thermal diffusion device illustrated in FIG. 1.

FIG. 3 is a partially enlarged sectional view schematically illustrating an example of a wick structure constituting the thermal diffusion device illustrated in FIG. 2.

FIG. 4A is an example of a plan view of the wick structure illustrated in FIG. 3 viewed from a supporting portion side. FIG. 4B is another example of a plan view of the wick structure illustrated in FIG. 3 viewed from the supporting portion side.

FIG. 5 is a partially enlarged sectional view schematically illustrating a first modification of the wick structure.

FIG. 6 is a partially enlarged sectional view schematically illustrating a second modification of the wick structure.

FIG. 7 is a partially enlarged sectional view schematically illustrating a third modification of the wick structure.

FIG. 8 is a plan view schematically illustrating a fourth modification of the wick structure.

FIG. 9 is a sectional view schematically illustrating a first modification of the wick structure illustrated in FIG. 7.

FIG. 10 is a sectional view schematically illustrating a second modification of the wick structure illustrated in FIG. 7.

FIG. 11 is a sectional view schematically illustrating a third modification of the wick structure illustrated in FIG. 7.

FIG. 12 is a sectional view schematically illustrating a fourth modification of the wick structure illustrated in FIG. 7.

FIG. 13 is a sectional view schematically illustrating a fifth modification of the wick structure illustrated in FIG. 7.

FIG. 14 is a sectional view schematically illustrating a sixth modification of the wick structure illustrated in FIG. 7.

### DESCRIPTION OF THE PREFERRED EMBODIMENTS

Hereinafter, a thermal diffusion device of the present description will be described. However, the present description is not limited to the embodiments below, and appropriate modifications can be made without departing from the spirit of the present description. Combinations of two or more individual configurations preferred in the present description set forth below are also included in the present description.

In the thermal diffusion device of the present description, a supporting portion and a portion having holes constituting a wick structure are composed of the same material and are integrally formed. Therefore, unevenness in adhesion does not occur between the supporting portion and the portion having holes. As a result, even when an interval of the supporting portions forming a liquid channel of a working medium is increased, the wick structure is structurally stable, and thus deterioration of the characteristics of the thermal diffusion device can be suppressed. In addition, since the supporting portion and the portion having holes are integrated, strength of the wick structure is also improved.

In the present specification, “being integrally formed” means that no interface exists between the supporting portion and the portion having holes, and specifically, a boundary cannot be discriminated between the supporting portion and the portion having holes. For example, in a wick structure in which a copper pillar as the supporting portion and a copper mesh as the portion having holes are fixed by diffusion jointing, spot welding, or the like, it is difficult to join the entire surface between the supporting portion and the portion having holes, and thus a gap is generated in a part between the supporting portion and the portion having holes. In such a wick structure, since a boundary can be discriminated between the supporting portion and the portion having holes, it can be said that the supporting portion and the portion having holes are not integrally formed.

In the following description, a vapor chamber is exemplified as an embodiment of the thermal diffusion device of the present description. The thermal diffusion device of the present description is applicable to a thermal diffusion device such as a heat pipe.

The drawings illustrated below are schematic, and dimensions, scales of aspect ratios, and the like thereof may differ from actual products.

In the present specification, a term indicating a relationship between elements (for example, the term “vertical”, “parallel”, “orthogonal”, or the like) and a term indicating a shape of an element are representations that mean to be substantially equivalent, for example, including approximately a few percentages different, rather than a representation indicating only a strict sense.

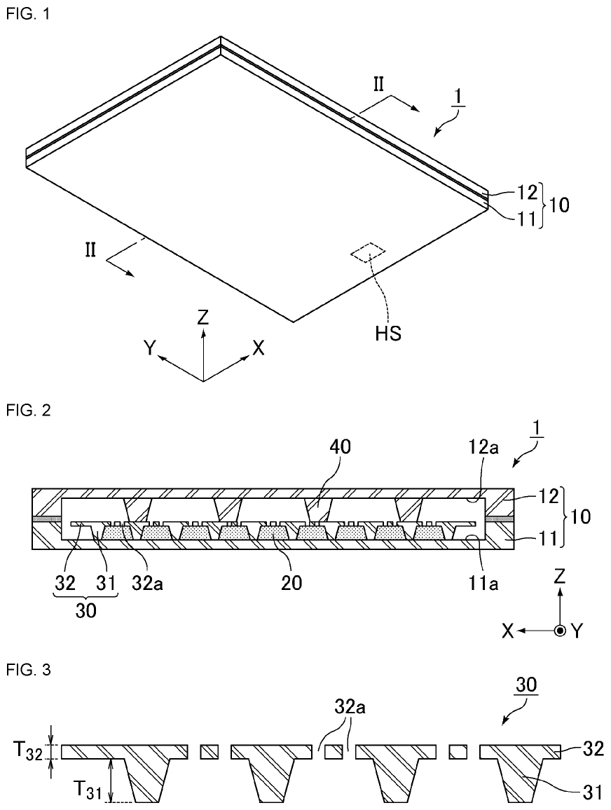

FIG. 1 is a perspective view schematically illustrating an example of a thermal diffusion device of the present description. FIG. 2 is an example of a sectional view taken along line II-II of the thermal diffusion device illustrated in FIG. 1.

A vapor chamber (thermal diffusion device) 1 illustrated in FIG. 1 includes a hollow housing 10 that is sealed in an airtight state. The housing 10 includes a first inner wall surface 11a and a second inner wall surface 12a facing each other in a thickness direction Z. The vapor chamber 1 further includes a working medium 20 sealed in an inner space of the housing 10, and a wick structure 30 disposed in the inner space of the housing 10.

In the housing 10, an evaporation portion that evaporates the sealed working medium 20 is set. As illustrated in FIG. 1, a heat source HS, which is a heating element, is disposed on an outer wall surface of the housing 10. Examples of the heat source HS include an electronic component of an electronic device such as a central processing unit (CPU). In the inner space of the housing 10, a portion that is located near the heat source HS and heated by the heat source HS corresponds to the evaporation portion.

The vapor chamber 1 preferably has a planar shape as a whole. That is, the housing 10 has a planar shape as a whole. Here, “a planar shape” includes a plate shape and a sheet shape, and indicates a shape in which a dimension in a width direction X (hereinafter, referred to as a width) and a dimension in a length direction Y (hereinafter, referred to as a length) are significantly large with respect to a dimension in the thickness direction Z (hereinafter, referred to as a thickness or a height), for example, a shape whose width and length are ten times, or preferably 100 times or larger than the thickness.

The size of the vapor chamber 1, that is, the size of the housing 10 is not particularly limited. The width and the length of the vapor chamber 1 can be appropriately set according to the application. Each of the width and the length of the vapor chamber 1 is, for example, 5 mm to 500 mm, 20 mm to 300 mm, or 50 mm to 200 mm. The width and the length of the vapor chamber 1 may be the same or may be different.

The housing 10 preferably includes a first sheet 11 and a second sheet 12, facing each other, whose outer edge portions are joined.

When the housing 10 includes the first sheet 11 and the second sheet 12, the material of the first sheet 11 and the second sheet 12 is not particularly limited as long as the material has characteristics suitable to the vapor chamber, for example, being thermally conductive, strong, pliable, and flexible. The material of the first sheet 11 and the second sheet 12 is preferably a metal, such as copper, nickel, aluminum, magnesium, titanium, iron, or an alloy containing these as a main component, and is particularly preferably copper. The material of the first sheet 11 and the second sheet 12 may be the same or may be different, but is preferably the same.

When the housing 10 includes the first sheet 11 and the second sheet 12, the outer edge portion of the first sheet 11 and the outer edge portion of the second sheet 12 are joined to each other. The joining method is not particularly limited, but for example, laser welding, resistance welding, diffusion jointing, braze welding, TIG welding (tungsten-inert gas welding), ultrasonic bonding, or resin sealing can be used, and the laser welding, the resistance welding, or the braze welding can be preferably used.

The thickness of each of the first sheet 11 and the second sheet 12 is not particularly limited, but is preferably 10 μm to 200 μm, more preferably 30 μm to 100 μm, or further more preferably 40 μm to 60 μm. The thickness of the first sheet 11 and the second sheet 12 may be the same, or may be different. In addition, the thickness of each of the first sheet 11 and the second sheet 12 may be the same over the entire sheet, or a part of the sheet may be thin.

The shape of the first sheet 11 and the second sheet 12 is not particularly limited. For example, each of the first sheet 11 and the second sheet 12 may have a shape whose outer edge portion is thicker than portions other than the outer edge portion.

The entire thickness of the vapor chamber 1 is not particularly limited, but is preferably 50 μm to 500 μm.

The planar shape of the housing 10 viewed in the thickness direction Z is not particularly limited, and examples of the shape include a polygonal shape such as a triangle or a rectangle, a circular shape, an elliptical shape, or a combination thereof. In addition, the planar shape of the housing 10 may be an L-shape, a C-shape (U-shape), a step shape, or the like. In addition, the housing 10 may include a penetration opening. The planar shape of the housing 10 may be a shape according to the application of the vapor chamber, the shape of a portion in which the vapor chamber is incorporated, or other components existing nearby.

The working medium 20 is not particularly limited as long as phase transition between gas and liquid is able to occur in the environment of the housing 10, and for example, water, alcohol, and CFC substitutes can be used. For example, the working medium 20 is an aqueous compound, and is preferably water.

The wick structure 30 has a capillary structure that can move the working medium 20 by capillary action. The capillary structure of the wick structure 30 may be a known structure that is used for a conventional vapor chamber.

The size and the shape of the wick structure 30 are not particularly limited, but for example, the wick structure 30 is preferably continuously disposed in the inner space of the housing 10. The wick structure 30 may be disposed in the entire inner space of the housing 10, or the wick structure 30 does not have to be disposed in a part of the inner space of the housing 10.

FIG. 3 is a partially enlarged sectional view schematically illustrating an example of a wick structure constituting the thermal diffusion device illustrated in FIG. 2.

As illustrated in FIGS. 2 and 3, the wick structure 30 includes a supporting portion 31 in contact with the first inner wall surface 11a and a portion having holes 32 composed of the same material as the supporting portion 31 and integrally formed with the supporting portion 31.

The material of the supporting portion 31 and the portion having holes 32 is not particularly limited, but examples of the material include resin, metal, a ceramic material, a combination thereof, and a laminated material thereof.

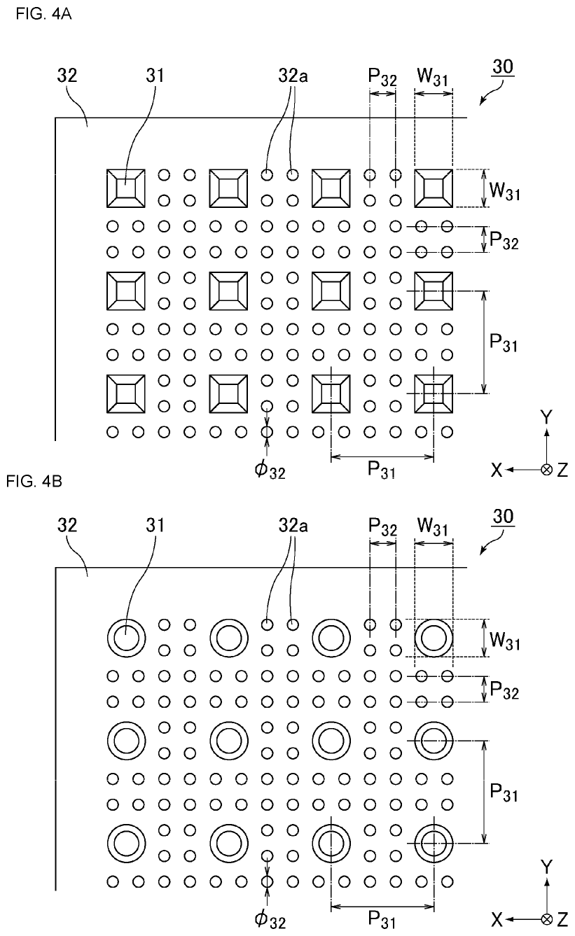

FIG. 4A is an example of a plan view of the wick structure illustrated in FIG. 3 viewed from the supporting portion side. FIG. 4B is another example of a plan view of the wick structure illustrated in FIG. 3 viewed from the supporting portion side.

In the wick structure 30, the supporting portion 31 includes a plurality of columnar members. Through holding of the working medium 20 in a liquid phase between the columnar members, heat transport performance of the vapor chamber 1 can be improved. Here, “columnar” indicates a shape in which the ratio of the length of the long side of the bottom surface to the length of the short side of the bottom surface is less than five times.

The shape of each columnar member is not particularly limited, but examples of the shape include a columnar shape, a prismatic shape, a truncated cone shape, and a truncated pyramid shape. In the example illustrated in FIG. 4A, the sectional shape vertical to a height direction of the supporting portion 31 is a square shape, and in the example illustrated in FIG. 4B, the sectional shape vertical to the height direction of the supporting portion 31 is a circular shape.

It is sufficient as long as the columnar member is relatively high compared to portions around the columnar member. Therefore, the columnar member includes a portion that is made relatively high by a recess formed on the first inner wall surface 11a, in addition to a portion projecting from the first inner wall surface 11a.

As the portion having holes 32, for example, a metal porous film, a sintered body, a porous body, or the like formed by etching processing or metal processing is used. The sintered body, which becomes the material of the portion having holes 32, may include, for example, a porous sintered body such as a metal porous sintered body and a ceramic porous sintered body, and preferably includes a copper or nickel porous sintered body. The porous body, which becomes the material of the portion having holes 32, may include, for example, a metal porous body, a ceramic porous body, a resin porous body, or the like.

The wick structure 30 in which the supporting portion 31 and the portion having holes 32 are integrally formed can be manufactured by, for example, an etching technique, a printing technique by multilayer coating, or other types of multilayer techniques.

The supporting portion 31 may be integrated with the housing 10, and may be, for example, formed by etching processing on the first inner wall surface 11a of the housing 10.

As illustrated in FIGS. 2 and 3, the supporting portion 31 preferably has a tapered shape whose width is decreased from the portion having holes 32 toward the first inner wall surface 11a. As a result, a depression of the portion having holes 32 between the supporting portions 31 can be suppressed, and the channel between the supporting portions 31 can be made wide on the housing 10 side. As a result, the permeability is improved, and the maximum heat transport amount is increased.

As illustrated in FIGS. 2, 3, 4A and 4B, when the portion having holes 32 is viewed in the thickness direction Z, it is preferable that a hole 32a of the portion having holes 32 does not exist in a region overlapping with each supporting portion 31. In this case, the working medium 20 is not easily trapped on the supporting portion 31.

The arrangement of the supporting portions 31 is not particularly limited, but the supporting portions 31 are preferably arranged at regular intervals in a predetermined region, and are more preferably arranged at regular intervals such that, for example, a distance between centers (pitch) of the supporting portions 31 is constant over the entire region.

The distance between centers of the supporting portions 31 (a length indicated by P₃₁ in FIG. 4A or FIG. 4B) is, for example, 60 μm to 800 μm. A width of each supporting portion 31 (a length indicated by W₃₁ in FIG. 4A or FIG. 4B) is, for example, 20 μm to 500 μm. A height of each supporting portion 31 (a length indicated by T₃₁ in FIG. 3) is, for example, 10 μm to 100 μm.

The arrangement of the holes 32a of the portion having holes 32 is not particularly limited, but the holes 32a are preferably arranged at regular intervals in a predetermined region, and are more preferably arranged at regular intervals such that, for example, a distance between centers (pitch) of the holes 32a of the portion having holes 32 is constant over the entire region.

The distance between centers of the holes 32a of the portion having holes 32 (a length indicated by P₃₂ in FIG. 4A or FIG. 4B) is, for example, 3 μm to 150 μm. A diameter of each hole 32a of the portion having holes 32 (a length indicated by φ₃₂ in FIG. 4A or FIG. 4B) is, for example, 1 μm to 100 μm. A thickness of the portion having holes 32 (a length indicated by T₃₂ in FIG. 3) is, for example, 5 μm to 50 μm.

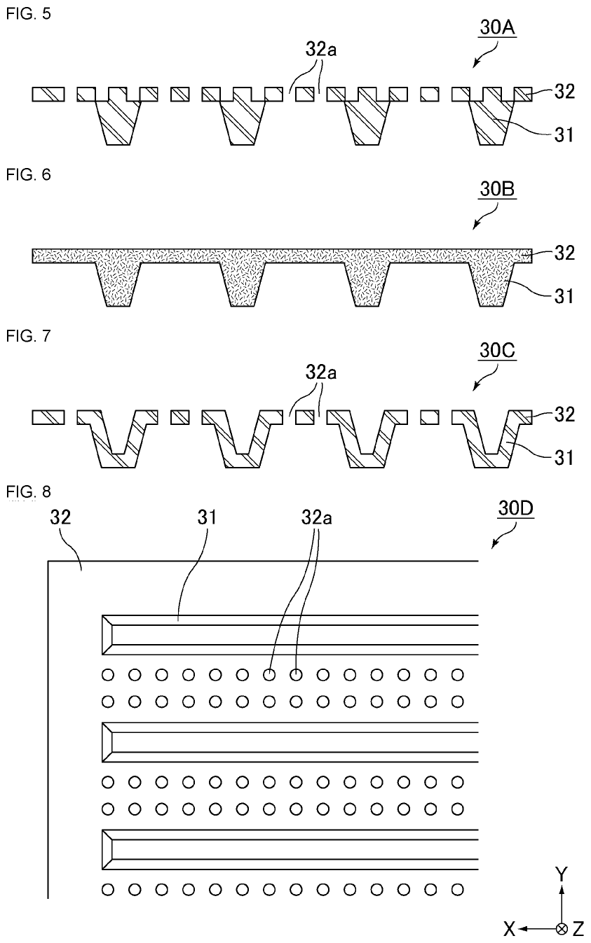

FIG. 5 is a partially enlarged sectional view schematically illustrating a first modification of the wick structure.

As shown in a wick structure 30A illustrated in FIG. 5, when the portion having holes 32 is viewed in the thickness direction z, the holes 32a of the portion having holes 32 may exist in a region overlapping with the supporting portion 31.

FIG. 6 is a partially enlarged sectional view schematically illustrating a second modification of the wick structure.

In a wick structure 30B illustrated in FIG. 6, the supporting portion 31 and the portion having holes 32 are composed of a porous material. Since the supporting portion 31 is also composed of a porous material, in addition to the portion having holes 32, the capillary action of the wick structure 30B can be improved.

Examples of the porous material of the supporting portion 31 and the portion having holes 32 include a porous sintered body such as a metal porous sintered body and a ceramic porous sintered body, or a porous body such as a metal porous body, a ceramic porous body, and a resin porous body.

The wick structure 30B composed of the porous material can be manufactured by a printing technique by multilayer coating using a metal paste or a ceramic paste. At this time, the metal or ceramic material content in the paste for forming the supporting portion 31 may be the same as the metal or ceramic material content in the paste for forming the portion having holes 32, may be less than the metal or ceramic material content in the paste for forming the portion having holes 32, or may be more than the metal or ceramic material content in the paste for forming the portion having holes 32. For example, when the metal or ceramic material content in the paste for forming the supporting portion 31 is made more than the metal or ceramic material content in the paste for forming the portion having holes 32, the density of the supporting portion 31 can be made higher than the density of the portion having holes 32. As a result, the strength of the supporting portion 31 can be increased.

FIG. 7 is a partially enlarged sectional view schematically illustrating a third modification of the wick structure.

In a wick structure 30C illustrated in FIG. 7, the supporting portion 31 is formed in a recessed portion that is recessed through bending of a part of a metal foil by press processing, for example. Since a vapor space is formed in the recessed portion of the supporting portion 31, thermal conductivity is improved. Not only in the example illustrated in FIG. 7, but also when press processing is performed on a metal foil, a through-hole may be formed in a portion recessed when a part of the metal foil is bent depending on the condition of the press processing.

In the wick structure 30C, the hole 32a of the portion having holes 32 can be formed through punching of a metal foil composing the wick structure 30 by press processing. In this case, the press processing for forming the supporting portion 31 and the press processing for forming the hole 32a of the portion having holes 32 can be collectively performed.

The thickness of the metal foil before being pressed is preferably constant. However, a bent portion of the metal foil may be thin. For the above reasons, it is preferable that in the wick structure 30C, the thickness of the supporting portion 31 is the same as the thickness of the portion having holes 32, or is less than the thickness of the portion having holes 32.

FIG. 8 is a plan view schematically illustrating a fourth modification of the wick structure. Note that FIG. 8 is a plan view of the wick structure viewed from the supporting portion side.

In a wick structure 30D illustrated in FIG. 8, the supporting portion 31 includes a plurality of rail-shaped members. Through holding of the working medium 20 in a liquid phase between the rail-shaped members, heat transport performance of the vapor chamber 1 can be improved. Here, “rail-shaped” indicates a shape in which the ratio of the length of the long side of the bottom surface to the length of the short side of the bottom surface is equal to or more than five times.

The sectional shape vertical to an extending direction of each rail-shaped member is not particularly limited, but examples of the sectional shape include a polygonal shape such as a rectangular shape, a semi-circular shape, a semi-elliptical shape, and a combination thereof.

It is sufficient as long as the rail-shaped member is relatively high compared to portions around the rail-shaped member. Therefore, the rail-shaped member includes a portion that is relatively high by a groove formed on the first inner wall surface 11a, in addition to a portion projecting from the first inner wall surface 11a.

As illustrated in FIG. 2, a supporting column 40 in contact with the second inner wall surface 12a may be disposed in the inner space of the housing 10. Through disposing of the supporting column 40 in the inner space of the housing 10, the housing 10 and the wick structure 30 can be supported.

The material of the supporting column 40 is not particularly limited, but examples of the material include resin, metal, a ceramic material, and a combination thereof, and a laminated material thereof. In addition, the supporting column 40 may be integrated with the housing 10, and may be, for example, formed by etching processing on the second inner wall surface 12a of the housing 10.

The shape of the supporting column 40 is not particularly limited as long as the shape can support the housing 10 and the wick structure 30, but examples of the sectional shape vertical to a height direction of the supporting column 40 include a polygonal shape such as a rectangular shape, a circular shape, and an elliptical shape.

The heights of the supporting columns 40 may be the same in the vapor chamber 1, or may be different.

In the sectional view illustrated in FIG. 2, the width of each supporting column 40 is not particularly limited as long as the width provides a strength for suppressing deformation of the housing 10, but the diameter of a substantially circular section vertical to the height direction of an end portion of the supporting column 40 is, for example, 100 μm to 2000 μm, and is preferably 300 μm to 1000 μm. When the diameter of the substantially circular section of the supporting column 40 is made large, deformation of the housing 10 can be further suppressed. On the other hand, when the diameter of the substantially circular section of the supporting column 40 is made small, a wider space in which vapor of the working medium 20 moves can be secured.

The arrangement of the supporting columns 40 is not particularly limited, but the supporting columns 40 are preferably arranged at regular intervals in a predetermined region, and are more preferably arranged at regular intervals such that, for example, a distance between the supporting columns 40 is constant over the entire region. Through arranging of the supporting columns 40 at regular intervals, uniform strength can be secured over the entire region of the vapor chamber 1.

The thermal diffusion device of the present description is not particularly limited to the above-described embodiments, and various modifications and changes can be made within the scope of the present description as to the configuration of the thermal diffusion device, manufacturing conditions, and the like.

For example, a peripheral edge of the hole of the portion having holes may be provided with a projecting portion that approaches the first inner wall surface or the second inner wall surface of the housing in the thickness direction. In this case, the projecting portion may be provided only in a part of the peripheral edge of the hole of the portion having holes, but is preferably provided over the entire peripheral edge of the hole of the portion having holes.

When the peripheral edge of the hole of the portion having holes is provided with the projecting portion, a hole whose peripheral edge is provided with the projecting portion that approaches the first inner wall surface, and a hole whose peripheral edge is provided with the projecting portion that approaches the second inner wall surface may be mixed, and a hole whose peripheral edge is provided with the projecting portion and a hole whose peripheral edge is not provided with the projecting portion may be mixed.

When the peripheral edge of the hole of the portion having holes is provided with the projecting portion that approaches the first inner wall surface, the projecting portion may have a lid portion that makes an opening of the projecting portion narrow in an end portion on the first inner wall surface side. Similarly, when the peripheral edge of the hole of the portion having holes is provided with the projecting portion that approaches the second inner wall surface, the projecting portion may have a lid portion that makes an opening of the projecting portion narrow in an end portion on the second inner wall surface side.

The projecting portion can be formed through punching of a metal or the like composing the portion having holes by press processing. In this case, the projecting portion may be simultaneously formed with the hole of the portion having holes, or may be formed separately from the hole of the portion having holes. When punching by press processing is performed, through appropriately adjusting of the depth of punching or the like, the shape of the projecting portion or the like can be adjusted. Note that the depth of punching indicates, for example, to what extent a punch is pushed into in a punching direction when the punch is used for performing punching.

The thickness of the projecting portion may be the same as the thickness of the portion having holes other than the projecting portion, or may be different. In addition, the thickness of the projecting portion may be the same as the thickness of the supporting portion, or may be different.

In particular, as shown in the wick structure 30C illustrated in FIG. 7, when the supporting portion is formed by press processing on a metal foil, press processing for forming the supporting portion and press processing for forming the hole of the portion having holes and the projecting portion are preferably collectively performed.

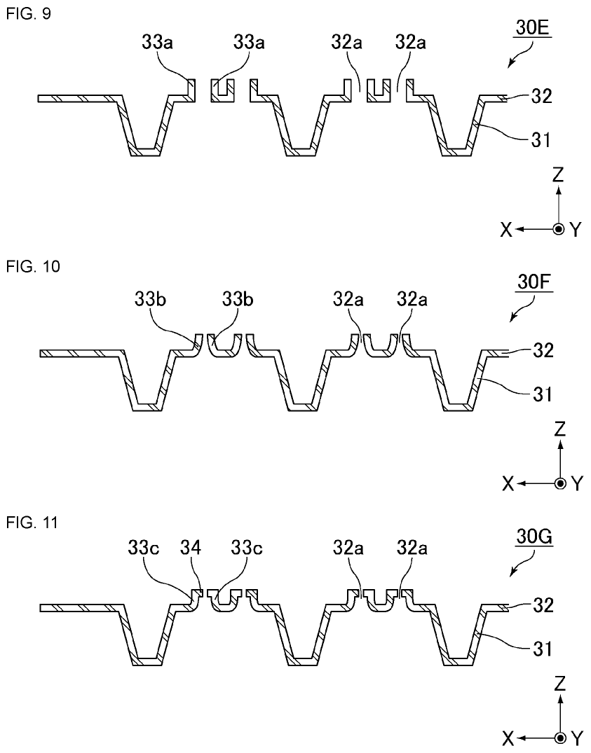

FIG. 9 is a sectional view schematically illustrating a first modification of the wick structure illustrated in FIG. 7.

In a wick structure 30E illustrated in FIG. 9, the peripheral edge of the hole 32a of the portion having holes 32 is provided with a projecting portion 33a that approaches the second inner wall surface 12a (see FIG. 2) of the housing 10 in the thickness direction Z. In the example illustrated in FIG. 9, the projecting portion 33a has a shape in which a distance between outer walls of the projecting portion 33a is constant in a direction approaching the second inner wall surface 12a (an upper side in FIG. 9) on a section extending in the thickness direction Z.

FIG. 10 is a sectional view schematically illustrating a second modification of the wick structure illustrated in FIG. 7.

In a wick structure 30F illustrated in FIG. 10, the peripheral edge of the hole 32a of the portion having holes 32 is provided with a projecting portion 33b that approaches the second inner wall surface 12a (see FIG. 2) of the housing 10 in the thickness direction Z. In the example illustrated in FIG. 10, the projecting portion 33b has a tapered shape in which a distance between outer walls of the projecting portion 33b becomes narrower in a direction approaching the second inner wall surface 12a (an upper side in FIG. 10) on the section extending in the thickness direction Z. The projecting portion 33b may have a reversed tapered shape in which a distance between the outer walls of the projecting portion 33b becomes wider in the direction approaching the second inner wall surface 12a (the upper side in FIG. 10) on the section extending in the thickness direction Z. In such cases, the projecting portion 33b may have a shape projecting toward the second inner wall surface 12a (the upper side in FIG. 10) on the section extending in the thickness direction Z, or may be a shape projecting toward the first inner wall surface 11a side (a lower side in FIG. 10).

FIG. 11 is a sectional view schematically illustrating a third modification of the wick structure illustrated in FIG. 7.

In a wick structure 30G illustrated in FIG. 11, the peripheral edge of the hole 32a of the portion having holes 32 is provided with a projecting portion 33c that approaches the second inner wall surface 12a (see FIG. 2) of the housing 10 in the thickness direction Z. The projecting portion 33c has a lid portion 34 that makes the opening of the projecting portion 33c narrow in an end portion on the second inner wall surface 12a side (an upper side in FIG. 11).

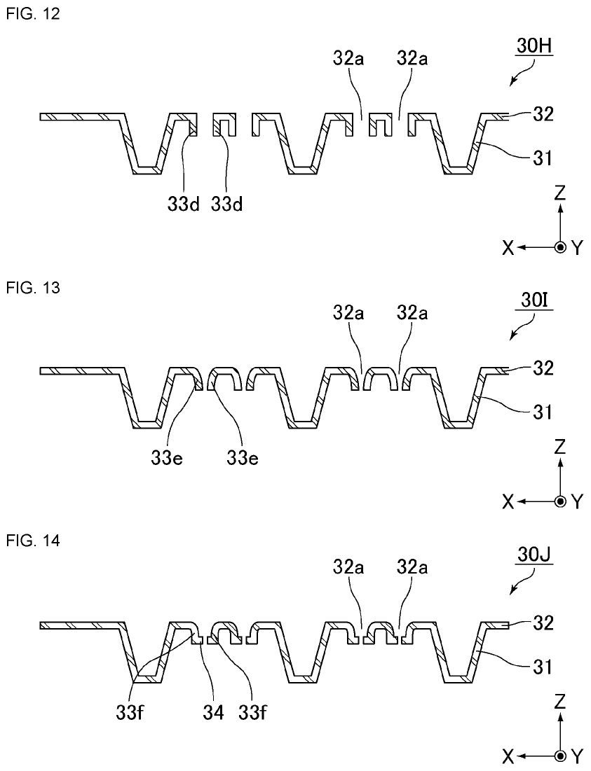

FIG. 12 is a sectional view schematically illustrating a fourth modification of the wick structure illustrated in FIG. 7.

In a wick structure 30H illustrated in FIG. 12, the peripheral edge of the hole 32a of the portion having holes 32 is provided with a projecting portion 33d that approaches the first inner wall surface 11a (see FIG. 2) of the housing 10 in the thickness direction Z. In the example illustrated in FIG. 12, the projecting portion 33d has a shape in which a distance between outer walls of the projecting portion 33d is constant in a direction approaching the first inner wall surface 11a (a lower side in FIG. 12) on a section extending in the thickness direction Z.

FIG. 13 is a sectional view schematically illustrating a fifth modification of the wick structure illustrated in FIG. 7.

In a wick structure 30I illustrated in FIG. 13, the peripheral edge of the hole 32a of the portion having holes 32 is provided with a projecting portion 33e that approaches the first inner wall surface 11a (see FIG. 2) of the housing 10 in the thickness direction Z. In the example illustrated in FIG. 13, the projecting portion 33e has a tapered shape in which a distance between outer walls of the projecting portion 33e becomes narrower in a direction approaching the first inner wall surface 11a (a lower side in FIG. 13) on a section extending in the thickness direction Z. The projecting portion 33e may have a reversed tapered shape in which a distance between the outer walls of the projecting portion 33e becomes wider in the direction approaching the first inner wall surface 11a (the lower side in FIG. 13) on the section extending in the thickness direction Z. In such cases, the projecting portion 33e may have a shape projecting toward the second inner wall surface 12a (an upper side in FIG. 13) on the section extending in the thickness direction z, or may have a shape projecting toward the first inner wall surface 11a side (the lower side in FIG. 13).

FIG. 14 is a sectional view schematically illustrating a sixth modification of the wick structure illustrated in FIG. 7.

In a wick structure 30J illustrated in FIG. 14, the peripheral edge of the hole 32a of the portion having holes 32 is provided with a projecting portion 33f that approaches the first inner wall surface 11a (see FIG. 2) of the housing 10 in the thickness direction Z. The projecting portion 33f has the lid portion 34 that makes the opening of the projecting portion 33f narrow in an end portion on the first inner wall surface 11a side (a lower side in FIG. 14).

In the thermal diffusion device of the present description, the housing may include one evaporation portion, or may include a plurality of evaporation portions. That is, an outer wall surface of the housing may be provided with one heat source, or may be provided with a plurality of heat sources. The number of the evaporation portions and the number of the heat sources are not particularly limited.

In the thermal diffusion device of the present description, when the housing includes the first sheet and the second sheet, the first sheet and the second sheet may overlap with each other such that end portions thereof coincide with each other, or may overlap with each other such that end portions thereof are displaced.

In the thermal diffusion device of the present description, when the housing includes the first sheet and the second sheet, the material of the first sheet may be different from the material of the second sheet. For example, when a strong material is used for the first sheet, a stress applied to the housing can be dispersed. In addition, when different materials are used for the first sheet and the second sheet, one of the sheets can obtain one function, and the other one can obtain another function. The above-described functions are not particularly limited, but examples of the functions include a heat conduction function and an electromagnetic wave shield function.

The thermal diffusion device of the present description can be mounted on an electronic device for the purpose of heat dissipation. Therefore, an electronic device including the thermal diffusion device of the present description is also part of the present description. Examples of the electronic device of the present description include a smartphone, a tablet terminal, a laptop computer, a game device, and a wearable device. As described above, the thermal diffusion device of the present description is able to operate independently without requiring external power and diffuse heat two-dimensionally at high speed by using evaporation latent heat and condensation latent heat of the working medium. Therefore, by the electronic device including the thermal diffusion device of the present description, in a limited space in the electronic device, effective heat dissipation can be achieved.

The thermal diffusion device of the present description can be used in a wide range of applications in fields of portable information terminals, and the like. For example, the present description can be used to decrease the temperature of a heat source of a CPU, or the like, and extend the use time of an electronic device, and can be used for smartphones, tablet terminals, laptop computers, and the like.

### REFERENCE SIGNS LIST

1 vapor chamber (thermal diffusion device)
10 housing
11 first sheet
11a first inner wall surface
12 second sheet
12a second inner wall surface
20 working medium
30, 30A, 30B, 30C, 30D, 30E, 30F, 30G, 30H, 30I, 30J wick structure
31 supporting portion
32 portion having holes
32a hole of portion having holes
33a, 33b, 33c, 33d, 33e, 33f projecting portion
34 lid portion
40 supporting column
HS heat source
P₃₁ distance between centers of supporting portions
P₃₂ distance between centers of holes of portion having holes
T₃₁ height of supporting portion
T₃₂ thickness of portion having holes
W₃₁ width of supporting portion
X width direction
Y length direction
Z thickness direction
φ₃₂ diameter of hole of portion having holes

1. A thermal diffusion device comprising:
a housing including a first inner wall surface and a second inner wall surface facing each other in a thickness direction;
a working medium sealed in an inner space of the housing; and
a wick structure in the inner space of the housing, the wick structure including a supporting portion in contact with the first inner wall surface and a portion having holes composed of a same material as the supporting portion and integral with the supporting portion.

2. The thermal diffusion device according to claim 1, wherein the supporting portion has a tapered shape with a width that decreases from the portion having holes toward the first inner wall surface.

3. The thermal diffusion device according to claim 1, wherein, when the portion having holes is viewed in the thickness direction, a hole of the portion having holes does not exist in a region overlapping with the supporting portion.

4. The thermal diffusion device according to claim 1, wherein the supporting portion and the portion having holes are composed of a porous material.

5. The thermal diffusion device according to claim 1, wherein a thickness of the supporting portion is same as or smaller that a thickness of the portion having holes.

6. The thermal diffusion device according to claim 1, wherein the supporting portion includes a plurality of columnar members.

7. The thermal diffusion device according to claim 1, wherein the supporting portion includes a plurality of rail-shaped members.

8. The thermal diffusion device according to claim 1, wherein, when the portion having holes is viewed in the thickness direction, a hole of the portion having holes exists in a region overlapping with the supporting portion.

9. The thermal diffusion device according to claim 1, wherein the supporting portion is a recessed portion relative to the portion having holes.

10. The thermal diffusion device according to claim 1, wherein a peripheral edge of a hole of the portion having holes includes a projecting portion that approaches the second inner wall surface of the housing 10 in the thickness direction.

11. The thermal diffusion device according to claim 10, wherein the projecting portion has a shape in which a distance between outer walls of the projecting portion is constant in a direction approaching the second inner wall surface in a cross section of the wick structure in the thickness direction.

12. The thermal diffusion device according to claim 10, wherein the projecting portion has a tapered shape in which a distance between outer walls of the projecting portion is not constant in a direction approaching the second inner wall surface in a cross section of the wick structure in the thickness direction.

13. The thermal diffusion device according to claim 10, wherein the projecting portion has a tapered shape in which a distance between outer walls of the projecting portion becomes narrower in a direction approaching the second inner wall surface in a cross section of the wick structure in the thickness direction.

14. The thermal diffusion device according to claim 10, wherein the projecting portion includes a lid portion that makes an opening at an end portion of the projecting portion narrow.

15. The thermal diffusion device according to claim 1, wherein a peripheral edge of a hole of the portion having holes includes a projecting portion that approaches the first inner wall surface of the housing 10 in the thickness direction.

16. The thermal diffusion device according to claim 15, wherein the projecting portion has a shape in which a distance between outer walls of the projecting portion is constant in a direction approaching the first inner wall surface in a cross section of the wick structure in the thickness direction.

17. The thermal diffusion device according to claim 15, wherein the projecting portion has a tapered shape in which a distance between outer walls of the projecting portion is not constant in a direction approaching the first inner wall surface in a cross section of the wick structure in the thickness direction.

18. The thermal diffusion device according to claim 15, wherein the projecting portion has a tapered shape in which a distance between outer walls of the projecting portion becomes narrower in a direction approaching the first inner wall surface in a cross section of the wick structure in the thickness direction.

19. The thermal diffusion device according to claim 15, wherein the projecting portion includes a lid portion that makes an opening at an end portion of the projecting portion narrow.

20. An electronic device comprising:
the thermal diffusion device according to claim 1.
